(19) United States
(12) Patent Application Publication
(10) Pub. No.: US 2024/0379689 A1
(43) Pub. Date: Nov. 14, 2024

(54) ARRAY SUBSTRATE AND DISPLAY PANEL

(71) Applicant: Guangzhou China Star Optoelectronics Semiconductor Display Technology Co., LTD., Guangzhou (CN)

(72) Inventor: Kai WANG, Guangzhou (CN)

(73) Assignee: Guangzhou China Star Optoelectronics Semiconductor Display Technology Co., LTD., Guangzhou (CN)

(21) Appl. No.: 18/509,379

(22) Filed: Nov. 15, 2023

(30) Foreign Application Priority Data
May 9, 2023 (CN) 202310520608.6

(51) Int. Cl. H01L 27/12

(52) U.S. Cl. CPC H01L 27/1248; H01L 27/124

(57) ABSTRACT

An array substrate and a display panel are provided. In the array substrate, the cushioning structure is arranged below the second connecting line, the side of the cushioning structure close to the via hole extends beyond the second connecting line, the third connecting line overlaps with the second connecting line and a portion of the cushioning structure that extends beyond the second connecting line, and the third connecting line passes through the via hole to connect the first connecting line, so that the third connecting line can connect the first connecting line and the second connecting line to realize the line turning of the first connecting line, and a border of the array substrate is reduced compared with the double-hole connection method.

### CROSS-REFERENCE TO RELATED APPLICATION

This application claims the benefit of priority of Chinese Patent Application No. 202310520608.6, filed on May 9, 2023, the disclosure of which is incorporated herein by reference in its entirety.

### TECHNICAL FIELD

The present disclosure relates to a field of display technologies, and in particular, to an array substrate and a display panel.

### DESCRIPTION OF RELATED ART

In a display device, a signal line in a gate layer is connected to connecting lines of source and drain layers, and then is connected to a driver chip through the connecting lines of the source and drain layers, so as to realize the scanning function of the display device. During a manufacturing process of existing display devices, in order to reduce mask plates for reducing the cost and improving the manufacturing efficiency, electrodes in a pixel electrode layer will be used to bridge the signal line in the gate layer and the connecting lines in the source and drain layers. Specifically, existing methods for overlapping the signal line and connecting lines by the electrodes in the pixel electrode layer include a half-overlapping hole method and double-hole connection method. However, the half-overlapping hole method is prone to electrostatic damage to the electrodes in the pixel electrode layer, thereby resulting in the problem of lower yield of the display device, and the double-hole connection method has the problem of occupying a larger space, thereby leading to larger border of the display device.

Therefore, there is a technical problem that the existing display devices cannot give consideration to higher yield and narrower border by connecting the signal line and the connecting lines through the electrodes in the pixel electrode layer.

### SUMMARY OF THE INVENTION

Embodiments of the present disclosure provide an array substrate and a display panel, which can alleviate the technical problem that the existing display devices cannot give consideration to higher yield and narrower border by connecting the signal line and the connecting lines through the electrodes in the pixel electrode layer.

An embodiment of the present disclosure provides an array substrate, including:
a substrate;
a first metal layer, disposed on one side of the substrate, the first metal layer includes a first connecting line;
a gate insulating layer, disposed on a side of the first metal layer facing away from the substrate, the gate insulating layer includes a via hole;
a second metal layer, disposed on a side of the gate insulating layer facing away from the first metal layer, the second metal layer includes a second connecting line; and
a pixel electrode layer, disposed on a side of the second metal layer facing away from the gate insulating layer, the pixel electrode layer includes a third connecting line;
wherein the array substrate further includes a cushioning structure, the cushioning structure is disposed between the second connecting line and the gate insulating layer, a side of the cushioning structure close to the via hole extends beyond the second connecting line, the third connecting line overlaps with the second connecting line and a portion of the cushioning structure that extends beyond the second connecting line, the third connecting line is connected to the first connecting line through the via hole, and the cushioning structure is in insulated contact with the second connecting line.

In an embodiment, the array substrate includes an active layer, the active layer is disposed between the gate insulating layer and the second metal layer, the active layer includes an active pattern and the cushioning structure, and the cushioning structure is electrically insulated from the active pattern.

In an embodiment, the active pattern includes a doped portion and a channel portion, and a dopant ion concentration of the cushioning structure is greater than or equal to a dopant ion concentration of the channel portion.

In an embodiment, the doped portion includes a first doping portion and a second doping portion, and the second doping portion is disposed between the first doping portion and the channel portion; a dopant ion concentration of the second doping portion is greater than a dopant ion concentration of the channel portion, and the dopant ion concentration of the second doping portion is less than the dopant ion concentration of the first doping portion; and the dopant ion concentration of the cushioning structure is equal to the dopant ion concentration of the second doping portion, or the dopant ion concentration of the cushioning structure is equal to the dopant ion concentration of the channel portion.

In an embodiment, the doped portion includes multiple parts, and the second metal layer further includes a source electrode and a drain electrode; and the source electrode and the drain electrode are respectively connected to the multiple parts of the doped portion, and the doped portion is in contact with the channel portion, and the dopant ion concentration of the cushioning structure is equal to the dopant ion concentration of the channel portion.

In an embodiment, the array substrate includes a cushioning layer and an active layer, the cushioning layer is disposed between the gate insulating layer and the second metal layer, and the cushioning layer includes the cushioning structure.

In an embodiment, an orthographic projection of the cushioning structure projected on the substrate is in contact with an orthographic projection of the via hole projected on the substrate.

In an embodiment, a spacing between a side surface of the side of the cushioning structure close to the via hole and a side surface of a side of the second connecting line close to the via hole is greater than or equal to 1 micrometer.

In an embodiment, a material of the cushioning structure includes one selected from a group consisting of indium gallium zinc oxide, zinc oxide, tin oxide, indium zinc oxide, gallium zinc oxide, zinc tin oxide, and indium tin oxide.

Further, an embodiment of the present disclosure provides a display panel, and the display panel includes the array substrate described in any one of the above embodiments.

Beneficial effects: the embodiments of the application provide an array substrate and a display panel; the array substrate include a substrate, a first metal layer, a gate insulate layer, a second metal layer and a pixel electrode layer. The first metal lay is arranged on a side of the substrate, and the first metal layer includes a first connecting line. The gate insulating layer is arranged on a side of the first metal layer facing away from the substrate, and the gate insulating layer includes a via hole. The second metal layer is arranged on a side of the gate insulating layer facing away from the first metal layer, and the second metal layer includes a second connecting line. The pixel electrode layer is arranged on a side of the second metal layer facing away from the gate insulating layer, and the pixel electrode layer includes a third connecting line. The array substrate further includes a cushioning structure, which is disposed between the second connecting line and the gate insulating layer. A side of the cushioning structure close to the via hole is disposed to extend beyond the second connecting line, the third connecting line is overlapped on the second connecting line and a part of the cushioning structure extended beyond the second connecting line, the third connecting line passes through the via hole and is connected to the first connecting line, and the cushioning structure is in insulated contact with the second connecting line. According to the present disclosure, by arranging the cushioning structure below the second connecting line, the side of the cushioning structure close to the via hole is disposed to extend beyond the second connecting line, the third connecting line is overlapped on the second connecting line and a part of the cushioning structure extended beyond the second connecting line, and the third connecting line passes through the via hole to connect the first connecting line, so that the third connecting line can connect the first connecting line and the second connecting line to realize the line turning of the first connecting line, and a border of the array substrate is reduced compared with the double-hole connection method. Further, the cushioning structure can increase a spacing between the first connecting line and the second connecting line, thereby reducing the probability of static electricity generation, improving the yield of the array substrate, and giving consideration to the higher yield and narrower border of the array substrate when the first connecting line and the second connecting line are connected through the third connecting line.

### BRIEF DESCRIPTION OF THE DRAWINGS

The technical solutions and other beneficial effects of the present disclosure will be apparent by describing specific embodiments of the present disclosure in detail combined with the attached drawings herein after.

FIG. 1 illustrates a schematic diagram of an existing display device.

FIG. 2 illustrates a first schematic diagram of an array substrate provided by an embodiment of the present disclosure.

FIG. 3 illustrates a second schematic diagram of an array substrate provided by an embodiment of the present disclosure.

FIG. 4 illustrates a schematic diagram of an array substrate corresponding to steps of a preparation method of the array substrate provided by an embodiment of the present disclosure.

### DETAILED DESCRIPTION OF SPECIFIC EMBODIMENTS OF THE INVENTION

Technical solutions in embodiments of the present disclosure will be described hereinafter clearly and completely in conjunction with accompanying drawings of the embodiments of the present disclosure. It is apparent that, the described embodiments are merely parts of embodiments of the present disclosure, not the whole embodiment. Based on the described embodiments in the present disclosure, all other embodiments obtained by those skilled in the art without creative work belong to the scope of protection of the present disclosure.

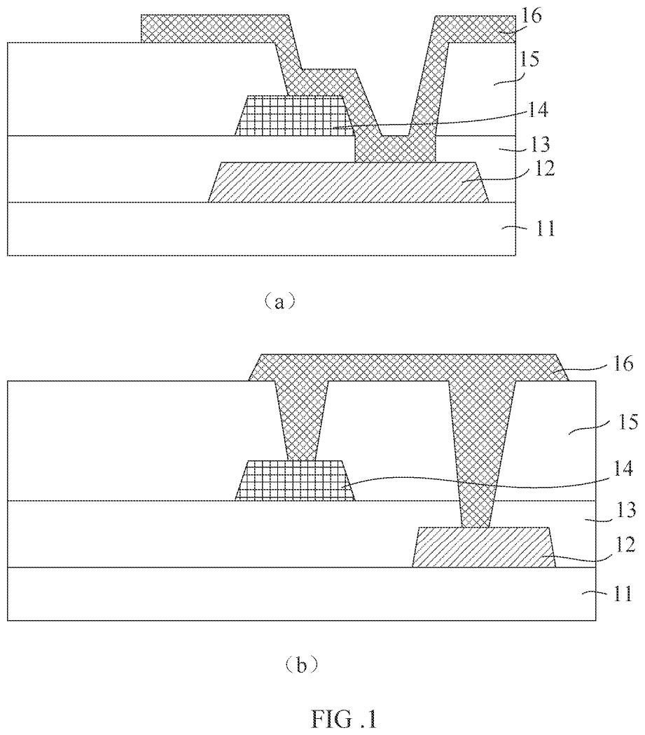

As shown in FIG. 1, (a) of FIG. 1 illustrates a schematic diagram of a display device in which an electrode is connected to a signal line and a connecting line by a half-overlapping hole, and (b) of FIG. 1 illustrates a schematic diagram of a display device in which an electrode is connected to a signal line and a connecting line by a double-hole. As shown in FIG. 1, the display device includes a substrate 11, a signal line 12, a first insulating layer 13, a connecting line 14, a second insulating layer 15, and an electrode 16. As shown in (a) of FIG. 1, in order to reduce the number of mask plates used in a preparation process of the existing display device, the signal line 12 is connected to the connecting line 14 through the electrode 16 in a half-overlapping method. However, because a side of the connecting line 14 close to the via hole is close to the signal line 12 in the via hole, the connecting line 14 is prone to tip discharge, thereby leading to burning of the electrode 16 and the failure of the connection between the connecting line 14 and the signal line 12. As shown in (b) of FIG. 1, in order to solve the problem of the existing display device caused by the half-overlapping hole method, the signal line 12 is connected to the connecting line 14 through a double-hole. Specifically, a spacing between the signal line 12 and the connecting line 14 is increased, and the electrode 16 is connected to the signal line 12 and the connecting line 14 through two via holes, but this method will lead to a larger border of display device. Therefore, there is a technical problem that the existing display devices cannot give consideration to higher yield and narrower border by connecting the signal line and the connecting lines through the electrodes in the pixel electrode layer.

In view of the above technical problem, an embodiment of the present disclosure provides an array substrate and a display panel for alleviating the above technical problem.

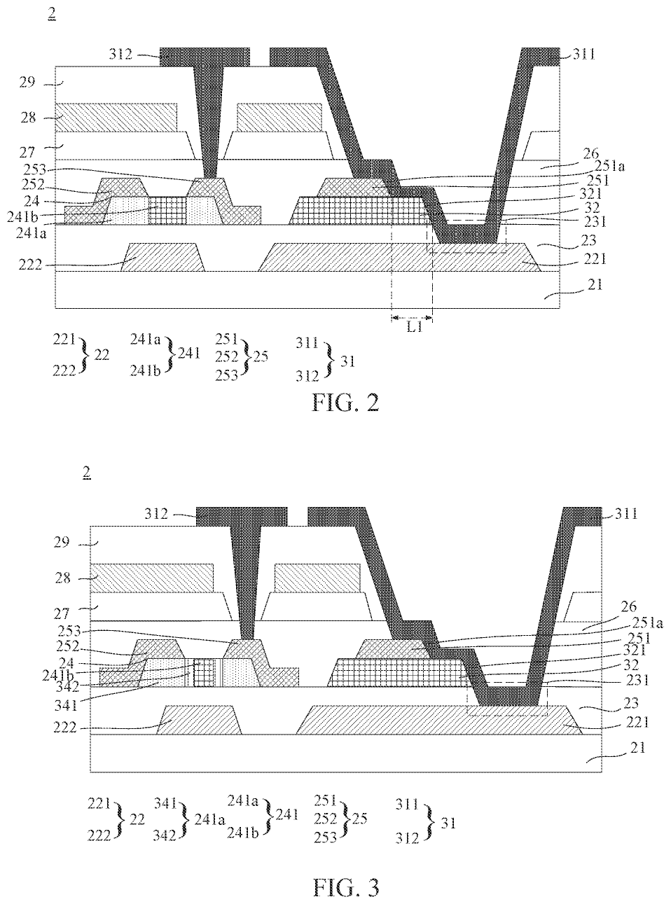

As shown in FIG. 2, an embodiment of the present disclosure provides an array substrate 2, and the array substrate 2 includes:

a substrate 21;

a first metal layer 22, first metal layer 22 is disposed on a side of the substrate 21, and the first metal layer 22 includes a first connecting line 221;

a gate insulating layer 23, the gate insulating layer 23 is disposed on a side of the first metal layer 22 facing away from the substrate 21, and the gate insulating layer 23 includes a via hole 231;

a second metal layer 25, the second metal layer 25 is disposed on a side of the gate insulating layer 23 facing away from the first metal layer 22, and the second metal layer 25 includes a second connecting line 251; and a pixel electrode layer 31, disposed on a side of the second metal layer 25 facing away from the gate insulating layer 23, and the pixel electrode layer 31 includes a third connecting line 311;

the array substrate 2 further includes a cushioning structure 32, the cushioning structure 32 is disposed between the second connecting line 251 and the gate insulating layer 23, a side of the cushioning structure 32 close to the via hole 231 is disposed to extend beyond the second connecting line 251, the third connecting line 311 is overlapped on the second connecting line 251 and a part of the cushioning structure 32 extended beyond the second connecting line 251, and the third connecting line 311 passes through the via hole 231 and is connected to the first connecting line 221, and the cushioning structure 32 is disposed to be insulated from the second connecting line 251.

For the array substrate provided by the embodiment of the present disclosure, the array substrate is provided with the cushioning structure below the second connecting line, the side of the cushioning structure close to the via hole is disposed to extend beyond the second connecting line, the third connecting line is overlapped on the second connecting line and a part of the cushioning structure extended beyond the second connecting line, and the third connecting line passes through the via hole to connect the first connecting line, so that the third connecting line can connect the first connecting line and the second connecting line to realize the line turning of the first connecting line, and a border of the array substrate is reduced compared with the double-hole connection method. Further, the cushioning structure can increase a spacing between the first connecting line and the second connecting line, thereby reducing the probability of static electricity generation, improving the yield of the array substrate, and giving consideration to the higher yield and narrower border of the array substrate when the first connecting line and the second connecting line are connected through the third connecting line.

Specifically, as shown in FIG. 2, a side surface 321 of the cushioning structure 32 close to the via hole 231 extends toward the via hole 231, and the side surface 321 of the cushioning structure 32 close to the via hole 231 is located on a right side of a side surface 251a of the second connecting line 251 close to the via hole 231, so that the side of the cushioning structure 32 close to the via hole 231 is disposed to extend beyond the second connecting line 251. Specifically, a width of a portion of the cushioning structure 32 extended beyond the second connecting line 251 on the side of the cushioning structure 32 close to the via hole 231 is a pacing L1 between the side surface 321 of the cushioning structure 32 close to the via hole 231 and the side surface 251a of the second connecting line 251 close to the via hole 231.

Specifically, since the side surface 321 of the cushioning structure 32 close to the via hole 231 and the side surface 251a of the second connecting line 251 close to the via hole 231 may be inclined surfaces, when the spacing between the side surface 321 of the cushioning structure 32 close to the via hole 231 and the side surface 251a of the second connecting line 251 close to the via hole 231 is determined, the spacing may be determined based on both an endpoint on the rightmost side of the side surface 321 of the cushioning structure 32 close to the via hole 231 and an endpoint on the rightmost side of the side surface 251a of the second connecting line 251 close to the via hole 231, but the embodiments of the present disclosure is not limited thereto.

For example, the spacing may be determined based on a middle point of the side surface 321 of the cushioning structure 32 close to the via hole 231 and a middle point of the side surface 251a of the second connecting line 251 close to the via hole 231, and the spacing may also be determined based on an endpoint on the leftmost side of the side surface 321 of the cushioning structure 32 close to the via hole 231 and an endpoint on the leftmost side of the side surface 251a of the second connecting line 251 close to the via hole 231.

Specifically, in the array substrate, because wirings are arranged in different metal layers, and some wirings need to cross other wirings to connect to binding terminals, therefore, crossing-line of the wiring of the first metal layer can be achieved through connecting the second connecting line of the second metal layer to the first connecting line. For example, if a scan line needs to cross over to the second metal layer to connect to a binding terminal, the first connecting line can be the scan line or a wiring connecting the scan line. When another signal line needs to cross over to the second metal layer to connect to a binding terminal, the first connecting line can also be the another signal lines or a wiring connecting the anther signal line.

Specifically, when the second connecting line is connected to a wiring of another film layer, the second connecting line can transmit signals of the wiring of the another film layer, so the second connecting line can be insulated from other wirings and electrodes in the second metal layer. For example, if the second metal layer includes a data line, a source electrode, and a drain electrode, the second connecting line needs to be insulated from the data line, the source electrode and, the drain electrode.

Specifically, when the third connecting line is connected to the first connecting line and the second connecting line, and a signal on the first connecting line will be transmitted on the third connecting line, so the third connecting line can be insulated from other signal lines and/or electrodes in the same layer. For example, if the pixel electrode layer also includes a pixel electrode, the pixel electrode is insulated from the third connecting line.

Specifically, the cushioning structure is disposed to be insulated from the second connecting line means that the cushioning structure is not conductive and cannot be conductive to the second connecting line.

Aiming at the problem that arranging the cushioning structure may increase process steps of the array substrate and reduce the preparation efficiency of the array substrate, in an embodiment, as shown in FIG. 2, the array substrate 2 further includes an active layer 24, the active layer 24 is disposed between the gate insulating layer 23 and the second metal layer 25, the active layer 24 includes an active pattern 241 and the cushioning structure 32, and the cushioning structure 32 is insulated from the active pattern 241. By making the active layer include the active pattern and the cushioning structure, the active pattern and the cushioning structure can be formed at the same time when the active layer is formed, and the cushioning structure does not need to be formed separately, so that the process steps of the array substrate do not need to be increased, and the preparation efficiency of the array substrate is improved. In addition, since the active layer includes the cushioning structure, a thickness of the array substrate will not be increased due to arranging of the cushioning structure, and the thickness of the array substrate will be reduced.

Specifically, as shown in FIG. 2, the active layer 24 includes the active pattern 241 and the cushioning structure 32. When preparing the active layer 24, the active pattern 241 and the cushioning structure 32 can be formed synchronously by using the same mask plate, and there is no need to increase process steps and mask plates, thus improving the preparation efficiency of the array substrate and reducing the cost. Further, since the cushioning structure 32 is located in the active layer 24, and a thickness of an insulating layer disposed on the cushioning structure 32 can be adjusted, so that a thickness of the array substrate does not need to be increased.

In an embodiment, as shown in FIG. 2, the active pattern 241 includes a doped portion 241a and a channel portion 241b, and a dopant ion concentration of the cushioning structure 32 is greater than or equal to that of the channel portion 241b. By making the dopant ion concentration of the cushioning structure greater than or equal to that of the channel portion, the cushioning structure can be formed without ion doping or partially ion doping, so that a preparation process of the cushioning structure and a preparation process of the active pattern can be synchronized, thereby avoid increasing of the preparation process of the array substrate; and the cushioning structure is insulated from the second connecting line, a spacing between the second connecting line and the first connecting line is increased, the probability of static electricity generation is reduced, and the yield of the display panel is improved.

Specifically, since the dopant ion concentration of the cushioning structure is greater than or equal to that of the channel portion, the cushioning structure may not be ion-doped or partially ion-doped, which cannot increase the process steps of the array substrate, and can keep the cushioning structure be insulated from the second connecting line.

In an embodiment, as shown in FIG. 3, the doped portion 241a includes a first doping portion 341 and a second doping portion 342. The second doping portion 342 is arranged between the first doping portion 341 and the channel portion 241b. A dopant ion concentration of the second doping portion 342 is greater than that of the channel portion 241b. The dopant ion concentration of the second doping portion 342 is smaller than that of the first doping portion 341. The dopant ion concentration of the cushioning structure 32 is equal to that of the second doping portion 342, or the dopant ion concentration of the cushioning structure 32 is equal to that of the channel portion 241b. By making the dopant ion concentration of the cushioning structure equal to the dopant ion concentration of the channel portion or the second doping portion, when the cushioning structure is formed, the cushioning structure can be shielded, and no ion doping is performed thereon, or the cushioning structure is lightly doped, which cannot increase the process steps of the array substrate, and the cushioning structure can be insulated from the second connecting line, which avoids static electricity generation between the first connecting line and the second connecting line and improves the yield of the array substrate.

Specifically, since the dopant ion concentration of the second doping portion is larger than that of the channel portion, and the dopant ion concentration of the second doping portion is smaller than that of the first doping portion, the problem that a potential barrier between the channel portion and the first doping portion is too large, resulting in excessive power consumption of the thin film transistor, can be avoided, and the channel portion will not in direct contact with the first doping portion, which avoids the leakage of the thin film transistor caused by the direct conduction of the channel portion.

Specifically, when forming the cushioning structure, the cushioning structure and the channel portion can be shielded, so that the dopant ion concentration of the cushioning structure is equal to the dopant ion concentration of the channel portion, and the cushioning structure and the second doping portion can be doped simultaneously, so that the dopant ion concentration of the cushioning structure is the same as the dopant ion concentration of the second doping portion.

In an embodiment, as shown in FIG. 2, the doped portion 241a includes multiple parts, and the second metal layer 25 further includes a source electrode 252 and a drain electrode 253, which are respectively connected to the multiple parts of the doped portion 241a, and the doped portion 241a is in contact with the channel portion 241b, and the dopant ion concentration of the cushioning structure 32 is equal to the dopant ion concentration of the channel portion 241b. By making the dopant ion concentration of the cushioning structure equal to the dopant ion concentration of the channel portion, when the cushioning structure is formed, the cushioning structure can be shielded and no ion doping is performed thereon, therefore, the process steps of the array substrate are not increased; moreover, since the cushioning structure is not ion doped, and the cushioning structure is non-conductive, the cushioning structure is insulated from the second connecting line, the spacing between the first connecting line and the second connecting line is increased, static electricity generation is avoided between the first connecting line and the second connecting line, and the yield of the array substrate is improved.

In an embodiment, a material of the active layer includes one selected from the group consisting of indium gallium zinc oxide, zinc oxide, tin oxide, indium zinc oxide, gallium zinc oxide, tin zinc oxide, and indium tin oxide. Since the active layer is formed by using metal oxide, after the cushioning structure is formed, the cushioning structure will not be etched when the gate insulating layer is dry-etched, so that the cushioning structure can increase the spacing between the first connecting line and the second connecting line, and the cushioning structure can be used as a mask plate for dry etching of the gate insulating layer to avoid static electricity generation and improve the yield of the array substrate.

Specifically, if the cushioning structure is formed by nonmetallic oxide, the non-metallic oxide will be etched away due to the subsequent requirement of dry-etching the gate insulating layer, which will lead to non-metallic oxide below the cushioning structure being etched away, and the spacing between the first connecting line and the second connecting line cannot be increased. According to the embodiment of the present disclosure, the active layer is made of metal oxide, so that when the gate insulating layer is dry etched, the cushioning structure can protect the gate insulating layer below the cushioning structure, thereby increasing the spacing between the first connecting line and the second connecting line, avoiding static electricity generation between the first connecting line and the second connecting line, and improving the yield of the array substrate. In addition, when the gate insulating layer is dry etched to form the via hole, the cushioning structure can be used as a mask plate, so that the number of mask plate plates is reduced, and alignment is not required, so that the preparation efficiency of the array substrate is improved. In addition, the cushioning structure is used as a mask plate, so that static electricity during dry etching of the gate insulating layer can be reduced, and the yield of the array substrate can be improved.

In an embodiment, the array substrate further includes a cushioning layer and an active layer, the cushioning layer is arranged disposed between the gate insulating layer and the second metal layer, and the cushioning layer includes the cushioning structure. When the cushioning structure is disposed, the cushioning layer can also be disposed, so that the cushioning structure is formed in the cushioning layer, the spacing between the first connecting line and the second connecting line is increased, static electricity generation is avoided between the first connecting line and the second connecting line, and the yield of the array substrate is improved.

In an embodiment, the material of the cushioning layer includes one selected from the group consisting of indium gallium zinc oxide, zinc oxide, tin oxide, indium zinc oxide, gallium zinc oxide, zinc tin oxide, and indium tin oxide. By using metal oxide to form the cushioning layer, after the cushioning structure is formed, the cushioning structure will not be etched when the gate insulating layer is dry-etched, so that the cushioning structure can increase the spacing between the first connecting line and the second connecting line, and the cushioning structure can be used as a mask plate for dry etching of the gate insulating layer to avoid static electricity generation and improve the yield of the array substrate.

The above embodiments have been described in detail by taking the active layer including the cushioning structure and the cushioning layer including the cushioning structure as examples, but the embodiment of the present disclosure is not limited thereto. For example, the cushioning structure can include multiple layers, and the active layer and the cushioning layer are respectively used to form the multiple layers of the cushioning structure.

In an embodiment, as shown in FIG. 2, a projection of the cushioning structure 32 on the substrate 21 is in contact with a projection of the via hole 231 on the substrate 21. By making the projection of the cushioning structure on the substrate contact with the projection of the via hole on the substrate, the cushioning structure can be used as a mask plate for etching the gate insulating layer, so that the number of mask plates is reduced, and alignment is not required, thereby improving the preparation efficiency of the array substrate; and by using the cushioning structure as the mask plate, static electricity during dry etching the gate insulating layer can be reduced, and the yield of the array substrate can be improved.

Specifically, after all of the film layers in the array substrate is formed, the gate insulating layer is etched to form the via hole, so that the third connecting line can pass through the via hole and be connected to the first connecting line. By using the cushioning structure as the mask plate for etching the gate insulating layer, a side of the cushioning structure close to the via hole and aside of the via hole close to the cushioning structure are in the same line, and the cushioning structure can protect the gate insulating layer below the cushioning structure, so that a spacing between an edge of the second connecting line close the via hole and a part of the first connecting line corresponding to the via hole position is increased, thereby avoiding static electricity generation and improving the yield of the array substrate.

In an embodiment, as shown in FIG. 2, the spacing L1 between the side surface 321 of the side of the cushioning structure 32 close to the via hole 231 and the side surface 251a of the side of the second connecting line 251 close to the via hole 231 is greater than or equal to 1 micrometer. By making a width of a portion of the cushioning structure extended beyond the second connecting line on the side of the cushioning structure close the via hole greater than or equal to 1 micrometer, a spacing between the side of the second connecting line close to the via hole and a position of the first connecting line corresponding to the via hole position is larger, which avoids static electricity generation between the first connecting line and the second connecting line and improves the yield of the array substrate.

In an embodiment, a material of the cushioning structure includes one selected from the group consisting of indium gallium zinc oxide, zinc oxide, tin oxide, indium zinc oxide, gallium zinc oxide, zinc tin oxide, and indium tin oxide. By using metal oxide to form the cushioning structure, after the cushioning structure is formed the cushioning structure will not be etched when the gate insulating layer is dry-etched, so that the cushioning structure can increase the spacing between the first connecting line and the second connecting line, and the cushioning structure can be used as a mask plate for dry etching of the gate insulating layer to avoid static electricity generation and improve the yield of the array substrate.

In an embodiment, as shown in FIG. 2, the first metal layer 22 further includes a gate electrode 222, and the gate electrode 222 is insulated from the first connecting line 221.

In an embodiment, as shown in FIG. 2, the array substrate 2 further includes a first passivation layer 26, an organic layer 27, a common electrode layer 28, and a second passivation layer 29.

Specifically, in FIG. 2, the common electrode layer 28 and the pixel electrode layer 31 are disposed in the array substrate as an example, but the embodiment of this application is not limited to this. For example, when the array substrate is applied to a liquid crystal display panel, the common electrode layer can be arranged on a color film substrate, and when the array substrate is applied to an organic light-emitting diode display panel, the array substrate can be arranged on the light-emitting layer.

In one embodiment, as shown in FIG. 2, the pixel electrode layer 31 further includes a pixel electrode 312, and the pixel electrode 312 is insulated from the third connecting line 311.

Further, an embodiment of the present disclosure provides a preparation method of an array substrate, which prepares the array substrate as described in any one of the above embodiments, and the preparation method of the array substrate includes the following steps:

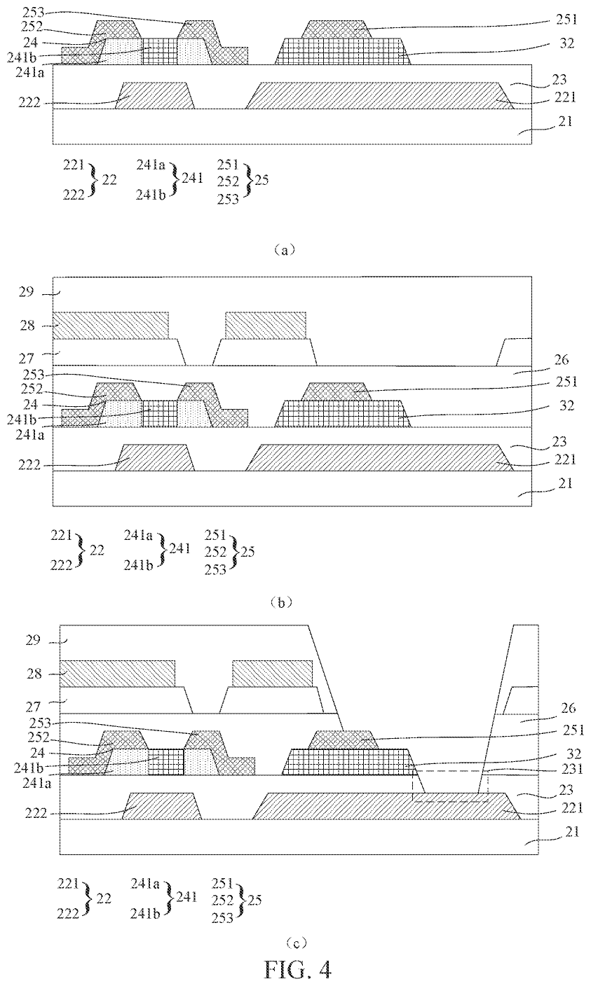

providing a substrate, and sequentially forming a first metal layer, a gate insulating layer, an active layer and a second metal layer on the substrate; and a structure of the array substrate corresponding to this step is shown in (a) of FIG. 4;

sequentially forming a first passivation layer, an organic layer, a common electrode layer and a second passivation layer on the second metal layer; and a structure of the array substrate corresponding to this step is shown in (b) of FIG. 4;

etching the gate insulating layer, the first passivation layer and the second passivation layer to form a via hole; and a structure of the array substrate corresponding to this step is shown in (c) of FIG. 4; and forming a pixel electrode layer on the second passivation layer; and a structure of the array substrate corresponding to this step is shown in FIG. 2.

Moreover, an embodiment of the present disclosure provides a display panel, which includes an array substrate as described in any one of the above embodiments.

In an embodiment, the display panel includes a liquid crystal display panel, which including the array substrate as described in any one of the above embodiments, a color film substrate, and a liquid crystal cell arranged between the array substrate and the color film substrate.

In an embodiment, the display panel includes an organic light emitting diode display panel, which includes the array substrate as described in any one of the above embodiments, and a light emitting layer and a common electrode layer disposed on the array substrate.

According to the above embodiments, the embodiments of the application provide an array substrate and a display panel; the array substrate include a substrate, a first metal layer, a gate insulate layer, a second metal layer and a pixel electrode layer. The first metal lay is arranged on a side of the substrate, and the first metal layer includes a first connecting line. The gate insulating layer is arranged on a side of the first metal layer facing away from the substrate, and the gate insulating layer includes a via hole. The second metal layer is arranged on a side of the gate insulating layer facing away from the first metal layer, and the second metal layer includes a second connecting line. The pixel electrode layer is arranged on a side of the second metal layer facing away from the gate insulating layer, and the pixel electrode layer includes a third connecting line. The array substrate further includes a cushioning structure, which is disposed between the second connecting line and the gate insulating layer. A side of the cushioning structure close to the via hole is disposed to extend beyond the second connecting line, the third connecting line is overlapped on the second connecting line and a part of the cushioning structure extended beyond the second connecting line, the third connecting line passes through the via hole and is connected to the first connecting line, and the cushioning structure is in insulated contact with the second connecting line. According to the present disclosure, by arranging the cushioning structure below the second connecting line, the side of the cushioning structure close to the via hole is disposed to extend beyond the second connecting line, the third connecting line is overlapped on the second connecting line and a part of the cushioning structure extended beyond the second connecting line, and the third connecting line passes through the via hole to connect the first connecting line, so that the third connecting line can connect the first connecting line and the second connecting line to realize the line turning of the first connecting line, and a border of the array substrate is reduced compared with the double-hole connection method. Further, the cushioning structure can increase a spacing between the first connecting line and the second connecting line, thereby reducing the probability of static electricity generation, improving the yield of the array substrate, and giving consideration to the higher yield and narrower border of the array substrate when the first connecting line and the second connecting line are connected through the third connecting line.

In the above-mentioned embodiments, the description of each embodiment has its own emphasis. For the parts not detailed in one embodiment, the related descriptions of other embodiments can be referred to.

The array substrate and the display panel provided by the embodiments of the present disclosure are described in detail above, and the principle and implementations of the present disclosure are explained by using specific examples. However, the description of the above embodiments is merely intended to facilitate understanding of the technical solutions and core ideas of the present disclosure. Those skilled in the art should understand that they could still modify the technical solutions recorded in the above-mentioned embodiments, or replace some technical features with equivalents. Further, these modifications or substitutions do not make the essence of the corresponding technical solutions deviate from the scope of the technical solution of each embodiment of the present disclosure.

What is claimed is:

1. An array substrate, comprising:
a substrate;
a first metal layer, disposed on one side of the substrate, wherein the first metal layer comprises a first connecting line;
a gate insulating layer, disposed on a side of the first metal layer facing away from the substrate, wherein the gate insulating layer comprises a via hole;
a second metal layer, disposed on a side of the gate insulating layer facing away from the first metal layer, wherein the second metal layer comprises a second connecting line; and
a pixel electrode layer, disposed on a side of the second metal layer facing away from the gate insulating layer, wherein the pixel electrode layer comprises a third connecting line;
wherein the array substrate further comprises a cushioning structure, the cushioning structure is disposed between the second connecting line and the gate insulating layer, a side of the cushioning structure close to the via hole extends beyond the second connecting line, the third connecting line overlaps with the second connecting line and a portion of the cushioning structure that extends beyond the second connecting line, the third connecting line is connected to the first connecting line through the via hole, and the cushioning structure is in insulated contact with the second connecting line.

2. The array substrate according to claim 1, further comprising an active layer, wherein the active layer is disposed between the gate insulating layer and the second metal layer, the active layer comprises an active pattern and the cushioning structure, and the cushioning structure is electrically insulated from the active pattern.

3. The array substrate according to claim 2, wherein the active pattern comprises a doped portion and a channel portion, and a dopant ion concentration of the cushioning structure is greater than or equal to a dopant ion concentration of the channel portion.

4. The array substrate according to claim 3, wherein the doped portion comprises a first doping portion and a second doping portion, and the second doping portion is disposed between the first doping portion and the channel portion;
a dopant ion concentration of the second doping portion is greater than a dopant ion concentration of the channel portion, and the dopant ion concentration of the second doping portion is less than the dopant ion concentration of the first doping portion; and
the dopant ion concentration of the cushioning structure is equal to the dopant ion concentration of the second doping portion, or the dopant ion concentration of the cushioning structure is equal to the dopant ion concentration of the channel portion.

5. The array substrate according to claim 3, wherein the doped portion comprises a plurality of parts, and the second metal layer further comprises a source electrode and a drain electrode; and
wherein the source electrode and the drain electrode are respectively connected to the plurality of parts of the doped portion, the doped portion is in contact with the channel portion, and the dopant ion concentration of the cushioning structure is equal to the dopant ion concentration of the channel portion.

6. The array substrate according to claim 1, further comprising a cushioning layer and an active layer, wherein the cushioning layer is disposed between the gate insulating layer and the second metal layer, and the cushioning layer comprises the cushioning structure.

7. The array substrate according to claim 1, wherein an orthographic projection of the cushioning structure projected on the substrate is in contact with an orthographic projection of the via hole projected on the substrate.

8. The array substrate according to claim 1, wherein a spacing between a side surface of the side of the cushioning structure close to the via hole and a side surface of a side of the second connecting line close to the via hole is greater than or equal to 1 micrometer.

9. The array substrate according to claim 1, wherein a material of the cushioning structure comprises one selected from a group consisting of indium gallium zinc oxide, zinc oxide, tin oxide, indium zinc oxide, gallium zinc oxide, zinc tin oxide, and indium tin oxide.

10. A display panel, comprising the array substrate according to claim 1.

11. The display panel according to claim 10, further comprising an active layer, wherein the active layer is disposed between the gate insulating layer and the second metal layer, the active layer comprises an active pattern and the cushioning structure, and the cushioning structure is electrically insulated from the active pattern.

12. The display panel according to claim 11, wherein the active pattern comprises a doped portion and a channel portion, and a dopant ion concentration of the cushioning structure is greater than or equal to a dopant ion concentration of the channel portion.

13. The display panel according to claim 12, wherein the doped portion comprises a first doping portion and a second doping portion, and the second doping portion is disposed between the first doping portion and the channel portion;
a dopant ion concentration of the second doping portion is greater than a dopant ion concentration of the channel portion, and the dopant ion concentration of the second doping portion is less than the dopant ion concentration of the first doping portion; and
the dopant ion concentration of the cushioning structure is equal to the dopant ion concentration of the second doping portion, or the dopant ion concentration of the cushioning structure is equal to the dopant ion concentration of the channel portion.

14. The display panel according to claim 12, wherein the doped portion comprises a plurality of parts, and the second metal layer further comprises a source electrode and a drain electrode; and
wherein the source electrode and the drain electrode are respectively connected to the plurality of parts of the doped portion, the doped portion is in contact with the channel portion, and the dopant ion concentration of the cushioning structure is equal to the dopant ion concentration of the channel portion.

15. The display panel according to claim 10, wherein further comprising a cushioning layer and an active layer, wherein the cushioning layer is disposed between the gate insulating layer and the second metal layer, and the cushioning layer comprises the cushioning structure.

16. The display panel according to claim 10, wherein an orthographic projection of the cushioning structure projected on the substrate is in contact with an orthographic projection of the via hole projected on the substrate.

17. The display panel according to claim 10, wherein a spacing between a side surface of the side of the cushioning structure close to the via hole and a side surface of a side of the second connecting line close to the via hole is greater than or equal to 1 micrometer.

18. The display panel according to claim 10, wherein a material of the cushioning structure comprises one selected from a group consisting of indium gallium zinc oxide, zinc oxide, tin oxide, indium zinc oxide, gallium zinc oxide, zinc tin oxide, and indium tin oxide.
